(19) United States
(12) Patent Application Publication
(10) Pub. No.: US 2015/0348811 A1
(43) Pub. Date: Dec. 3, 2015

(54) SUBSTRATE PROCESSING SYSTEM AND METHOD OF PROCESSING SUBSTRATES

(71) Applicants: Oliver GRAW, Alzenau (DE); Erkan KOPARAL, Nidderau (DE)

(72) Inventors: Oliver GRAW, Alzenau (DE); Erkan KOPARAL, Nidderau (DE)

(73) Assignee: Applied Materials, Inc., Santa Clara, CA (US)

(21) Appl. No.: 14/426,091

(22) PCT Filed: Sep. 10, 2012
(86) PCT No.: PCT/EP2012/067656

§ 371 Date: Aug. 7, 2015

(51) Int. Cl. H01L 21/677; C23C 14/34

(52) U.S. Cl. CPC H01L 21/67745; H01L 21/67742; H01L 21/67748; C23C 14/34

(57) ABSTRACT

A substrate processing system is provided. The substrate processing system includes a front end module, a load module, and a process module. The modules are arranged for substrate transfer between these modules along a transport direction. At least one of the front end module, load module and process module includes a transfer device providing at least two individual tracks for supporting a substrate or substrate carrier. Two or more of the at least two tracks of the transfer device may be movable relatively to each other in a switch direction perpendicular to the transport direction. At least the first load module, the second load module and the process module may each include a dual-track transfer device.

### FIELD OF THE INVENTION

Embodiments of the present invention relate to substrate processing systems including transfer devices for substrate transfer and to methods of processing a substrate in a substrate processing system. Some embodiments relate to substrate processing systems for processing substantially vertically oriented substrates. Specifically, some embodiments relate to dual-track substrate processing systems.

### BACKGROUND OF THE INVENTION

In a number of technical applications, e.g., TFT metallization processes, layers of different materials are deposited onto each other over a substrate. Typically, this is done in a sequence of coating or deposition steps, e.g., sputtering steps, wherein other processing steps like etching or structuring might also be provided before, between, or after the various deposition steps. For example, a multi-layer stack with a sequence of “material one”-“material two”-“material one” can be deposited. Due to different coating rates in different process steps and due to different thicknesses of the layers, the processing time in the processing chambers for depositing different layers may vary considerably.

In order to deposit a multiple layer stack, a number of configurations of processing modules can be provided. For example, in-line arrangements of deposition modules can be used as well as cluster arrangements. A typical cluster arrangement comprises a central handling module and a number of processing or deposition modules connected thereto. The coating modules may be equipped to carry out the same or different processes. A typical in-line system includes a number of subsequent processing modules, wherein processing steps are conducted in one chamber after the other such that a plurality of substrates can continuously or quasi-continuously be processed with the in-line system.

Cluster tools allow for different cycle times but the handling of substrates may be quite complex, requiring a complicated transfer system provided in the central handling chamber. The processing tact in in-line systems is typically determined by the longest processing time. Two transport paths may be provided so that a first substrate may overtake a second substrate that is being coated.

Still, there remains a need for improved substrate processing systems in which, for a given output capacity, the number of modules and therefore the costs may be reduced, or in which, for the same or comparable number of modules, the output capacity can be increased. There is also a need for improved methods of process conduct to reduce the tact time, and for systems capable of carrying out such methods.

### SUMMARY

In light of the above, a system and a method according to the independent claims are provided. Further details can be found in the dependent claims, the description, and the drawings.

According to an embodiment, a substrate processing system is provided. The substrate processing system includes a front end module, a load module, and a process module. The substrate processing system may include a second load module. The modules are arranged for substrate transfer between these modules along a transport direction. At least one of the front end module, load module and process module includes a substrate transfer device providing at least two individual tracks for supporting a substrate or substrate carrier. Two or more of the at least two tracks of the substrate transfer device may be movable relatively to each other in a switch direction perpendicular to the transport direction. The substrate transfer device may be a dual-track substrate transfer device, and the two tracks of the dual-track substrate transfer device may be movable relatively to each other in a switch direction perpendicular to the transport direction. At least the first load module, the second load module and the process module may each include a dual-track transfer device.

According to another embodiment, a method of processing a substrate in a substrate processing system is provided. The method includes transferring the substrate into a vacuum portion of the substrate processing system along a transport direction. The method further includes performing relative movement between a first track and a second track. The first track supports the substrate. The relative movement is performed in a switch direction perpendicular to the transport direction in a processing module of the vacuum portion. The method further includes depositing a layer onto the substrate in the vacuum processing module.

The disclosure is also directed to a system for carrying out the disclosed methods, including apparatus parts for performing each of the described method steps. These method steps may be performed by way of hardware components, a computer programmed by appropriate software, by any combination of the two or in any other manner. Furthermore, the disclosure is also directed to methods by which the described system operates or is manufactured. It includes method steps for carrying out every function of the system.

### BRIEF DESCRIPTION OF THE DRAWINGS

So that the manner in which the above recited features can be understood in detail, a more particular description may be had by reference to embodiments. The accompanying drawings relate to embodiments and are described in the following:

FIGS. 1-3 show schematic illustrations of substrate processing systems according to embodiments described herein;

FIGS. 4-7 show schematic illustrations of a substrate processing method depositing one layer on a substrate and a corresponding substrate processing system according to embodiments described herein;

FIGS. 8-14 show schematic illustrations of a substrate processing method depositing three layers on a substrate and a corresponding substrate processing system according to embodiments described herein;

FIGS. 15-19 show schematic illustrations of a substrate processing method depositing three layers on a substrate and a corresponding substrate processing system according to embodiments described herein;

FIG. 20 shows a transfer device according to embodiments described herein; and

FIGS. 21-23 show substrate support elements of a transfer device and illustrate a method of moving substrates in a transfer device according to embodiments described herein;

FIGS. 24-27 show substrate support elements of a transfer device and illustrate a method of moving substrates in a transfer device according to embodiments described herein; and

FIG. 28 is a block diagram illustrating a method of processing a substrate according to embodiments described herein.

### DETAILED DESCRIPTION OF THE INVENTION

Reference will now be made in detail to the various exemplary embodiments, one or more examples of which are illustrated in each figure. Each example is provided by way of explanation and is not meant as a limitation. For example, features illustrated or described as part of one embodiment can be used on or in conjunction with other embodiments to yield yet further embodiments. It is intended that the present disclosure includes such modifications and variations.

Within the following description of the drawings, the same reference numbers refer to the same or similar components. Generally, only the differences with respect to the individual embodiments are described. The structures shown in the drawings are not necessarily depicted true to scale or angle, and may exaggerate features for a better understanding of the corresponding embodiments.

The term “direction” as used herein is not limited to the meaning of a vectored direction (“from A to B”), but includes both vectored directions in which a straight line can be followed (“from A to B” and “from B to A”). For example, the vertical direction shall include both the notions of up and down. Directions are therefore indicated by arrows with two arrow heads in the drawings.

The term “substrate” as used herein shall embrace substrates, such as glass substrates. Thereby, the substrates are typically large area substrates with a size of 1.4 m² and above, typically 5 m² and above. For example, substrate sizes of 1.43 m² (Gen5) and above, such as 5.5 m² (Gen8.5), 9 m² (Gen10) or larger can be realized.

Typically, the substrates are vertically oriented or substantially vertically oriented. Thereby, it is to be understood that a substantially vertically oriented substrate can have some deviation from a vertical orientation in a processing system in order to allow for stable transport with an inclination by a few degrees, e.g., at most 15° or at most 10°, e.g., from 5° to 7° or less. The substrates are then said to be substantially or essentially vertically oriented. A substrate is substantially vertically oriented if the normal to its largest surfaces (front and back surfaces) is substantially horizontally oriented, i.e., the normal has a tilt of at most a few degrees, e.g., at most 15° or at most 10°, e.g., from 5° to 7° or less. At least one of the largest surfaces, i.e., at least one of the front and back surfaces, is typically coated in substrate processing systems in which a substrate transfer device according to embodiments described herein may be used. A substantially horizontally oriented substrate has a normal to its largest surfaces that is tilted at most a few degrees from the vertical direction, such as at most 15° or at most 10°, such as from 5° to 7° or less.

According to an embodiment, a substrate processing system is provided. The substrate processing system may be a system for processing, in particular coating, a substantially vertically oriented substrate. The substrate processing system may be an inline system. The substrate processing system includes a front end module, a load module, and a process module. The substrate processing system may include further load or process modules, e.g., a second load module and/or a second, third or fourth process module. In embodiments with two load modules, the first load module may connected to a first pump system adapted to pump down the first load module to an intermediate vacuum, and the second load module may be connected to a second pump system adapted to pump down the second load module to a high vacuum. The intermediate vacuum may be in the range of 0.05 mbar to 1 mbar, such as about 0.1 mbar. The high vacuum may be 0.001 mbar or less, typically in the range from 10⁻⁵ mbar to 10⁻⁴ mbar, such as about 5*10⁻⁵ mbar.

In some embodiments, the front end module is adapted for loading substrates into carriers. The front end module may form an atmospheric portion of the substrate processing system, i.e., a portion not under vacuum. The load module or the load modules may be a lock between an atmospheric portion and a vacuum portion of the substrate processing system. Load modules may be regarded as loading substrates or substrate carriers into the vacuum portion or unloading them therefrom. The vacuum portion may include the process module(s). The process module(s) may be vacuum process module(s). The high vacuum may be present in modules of the vacuum portion of the substrate processing system.

The front end module, load module and process module may be arranged for substrate transfer between these modules along a transport direction. The substrates may be transferred in respective carriers. The substrate processing system may have at least two transport paths extending parallel to each other in the transport direction. Typically, the substrate processing system has a first transport path and a second transport path. The first transport path and the second transport path are displaced with respect to each other in a direction perpendicular to the transport direction. This direction will be called switch direction.

At least one of the front end module, load module and process module includes a substrate transfer device, e.g., a dual-track substrate transfer device or triple-track substrate transfer device or quadruple-track substrate transfer device. The process module may be the last module in a row of modules that starts with the front end module. The process module may include the substrate transfer device. A dual-track substrate transfer device provides two individual tracks for supporting a substrate or substrate carrier, a triple-track substrate transfer device provides three individual tracks for supporting a substrate or substrate carrier, a quadruple-track substrate transfer device provides four individual tracks for supporting a substrate or substrate carrier, and an n-tuple-track substrate transfer device provides n individual tracks for supporting a substrate or substrate carrier, where n is a natural number. A track is a space defined that can support a substrate or substrate carrier. The track may be defined by a substrate support assembly or by its support elements. Any number m of tracks of an n-tuple-track substrate transfer may be movable relatively to each other in at least one direction perpendicular to the transport direction, in particular in the switch direction, where m is an integer out of the range from 0 to n. In other words, two or more of the at least two tracks of a substrate transfer device may be movable relatively to each other at least in the switch direction. In a dual-track substrate transfer device, the two tracks may be movable relatively to each other in at least one direction perpendicular to the transport direction, in particular in the switch direction.

A dual-track substrate transfer device of this kind will be called relatively moveable dual-track substrate transfer device, e.g., in contrast to fixed dual-track substrate transfer devices where the tracks can not be moved at all or in contrast to only rigidly moveable transfer devices like the rigidly moveable triple-track transferring means of WO 2009/156196 A1. The term ‘rigidly moveable’ means that the tracks can only be moved as a group or combination, keeping their fixed distances to each other. The content of WO 2009/156196 A1 is incorporated herein by reference in as far as it is compatible with the content of the present disclosure. The capability of relative movement of the two tracks in the switch direction allows saving space in a processing region where deposition of layers onto substrates takes place in a process module as compared to the rigidly moveable triple-track solution of WO 2009/156196 A1. Saving this space may be positively influence the quality of the deposition process. The capability of relative movement also increases the flexibility with respect to process conduct, therefore possibly allowing improved conduct of substrate processing with reduced tact times.

For short, a module including exactly two tracks will be called a dual-track module, e.g., a dual-track swing module or a dual-track process module. A dual-track module where the tracks have fixed locations will be called a fixed dual-track module, and a dual-track module as described above where the two tracks can be moved relatively to each other will be called a relatively moveable dual-track module. The transfer devices will be called with similar nomenclature, e.g., fixed dual-track transfer device for a transfer device whose tracks are stationary, at fixed locations. An analog nomenclature applies to triple, quadruple or n-tuple devices, modules and systems. These will be called ‘fixed’ or ‘rigidly moveable’, as the case may be, if none of the n tracks are relatively moveable to each other, and will be called ‘fully relatively moveable’ if all n tracks are relatively moveable to each other. For simplicity, dual-track substrate transfer devices with two tracks will be described in the following. It should be understood that any of the features described can also apply to some or all of the tracks or components of triple, quadruple and n-tuple devices, modules and systems without further recitation.

Two tracks of a substrate transfer device may be movable independently of each other at least in the switch direction. The front end module, process module or other modules such as transfer modules may be configured such that the two tracks may pass each other in the switch direction. Passing each other means the following. Let X be a plane having a normal that is parallel to the normal of the first and second tracks, where the plane X is not lying between the tracks when viewed in the switch direction. If, at one point in time, the first track is closer to the plane X measured in the switch direction than the second track, then the proximity relation is inverted after the first and second tracks have passed each other. After passing, the second track is closer to the plane X measured in the switch direction than the first track. The two tracks may also said to have been switched.

The first track may be aligned with the first transport path, and may be aligned also with the second transport path at a different time. In other words, the first track may be alignable with the first transport path and alternatively with the second transport path. The second track may be aligned with the first transport path, and may be aligned also with the second transport path at a different time. In other words, the second track may be alignable with the first transport path and alternatively with the second transport path.

In process modules, the first track and/or second track may be alignable with a process position. The process position is typically closer to a deposition source than the first and second transport paths. A substrate or substrate carrier may be brought into alignment with a deposition mask in the process position. The deposition mask can be immovable at a fixed location with respect to the deposition source. The process position might coincide with a section of the first or second transport path in a process module. However, then a deposition mask and possibly even the deposition source might need to be moved towards the substrate or substrate carrier for the deposition of a layer. A process module may include more than one deposition source, e.g., two deposition sources. Then, there may be more than one process position per process module. A process module with more than one deposition source may be a triple-track or even quadruple-track module, e.g., a fully relatively moveable triple-track or quadruple track module. The tracks thereof may be alignable with the more than one process positions.

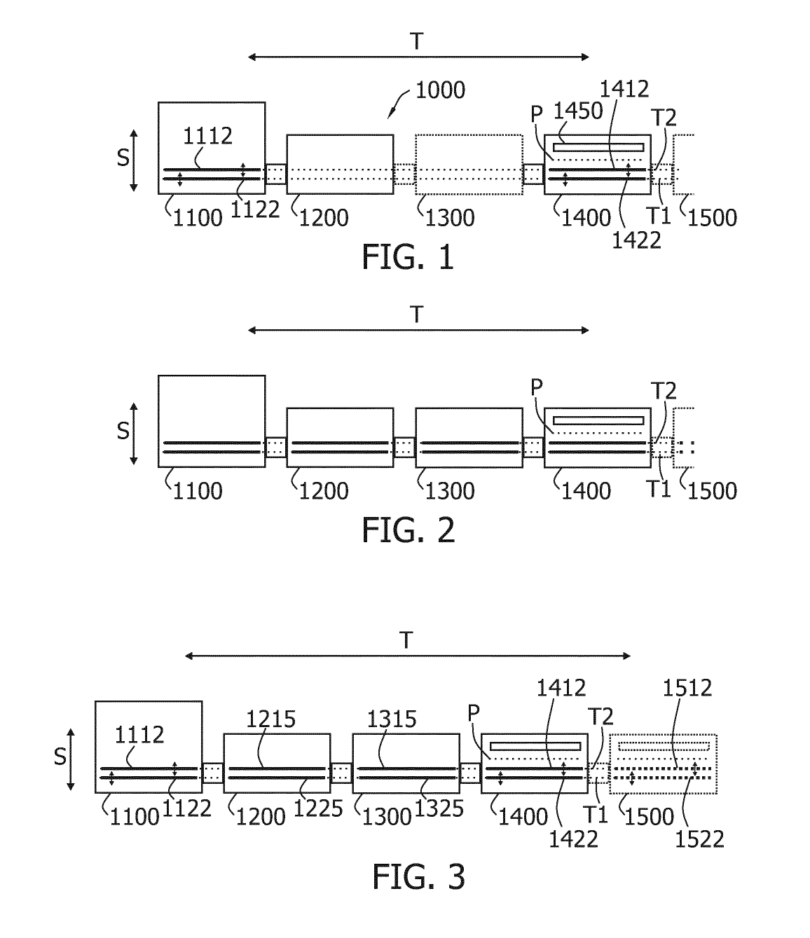

FIG. 1 schematically shows an embodiment of a substrate processing system 1000. FIG. 1 represents a top view if (substantially) vertically oriented substrates are processed, and represents a side view if (substantially) horizontally oriented substrates are processed, e.g., in sputter down process modules. The substrate processing system 1000 includes a front end module 1100, a load module 1200, and process module 1400. The process module 1400 includes a deposition source 1450. Deposition sources, according to embodiments described herein, may be, e.g., sputter sources, more specifically rotary target sputter sources. Rotary targets may enable high deposition rates via superior cooling of the target surface as compared to planar target technology. A process position P is shown in the process module 1400. The front end module 1100 may be a swing module for loading substrates into carriers and unloading them from their carriers. The swing module may be a dual-track swing module including a dual-track transfer device that provides two tracks for supporting a substrate or substrate carrier, wherein the two tracks are movable relatively to each other in the switch direction. Alternatively the front end module may include one or more robots such as a 6-axis robot for substrate loading and unloading. According to a further alternative, the front end module may include a device for substantially vertical substrate loading and unloading.

The substrate process module 1000 may optionally include further modules, e.g., a second load module 1300 and/or one or more further modules indicated by reference sign 1500, e.g., further process modules. These optional modules are shown in dotted lines in FIG. 1. Two transport paths T1 and T2 extend along the transport direction T and are spaced apart in a switch direction S. The front end module 1100, if embodied in the form of a swing module, may include a relatively moveable dual-track substrate transfer device having two tracks 1112 and 1122. Double-headed arrows in FIG. 1 indicate that the tracks 1112 and 1122 are moveable relatively to each other, or even independently of each other, at least in the switch direction S. The process module 1400 is shown to include a relatively moveable dual-track substrate transfer device having two tracks 1412 and 1422. Double-headed arrows in FIG. 1 indicate that the tracks 1412 and 1422 are moveable relatively to each other, or even independently of each other, at least in the switch direction S.

The modules are arranged for substrate transfer between every pair of neighboring modules. For example, as will be described in more detail below, substrates or substrate carriers loaded with respective substrates may be exchanged, typically simultaneously exchanged, between neighboring modules. A substrate or substrate carrier may be moved with its track supporting it from one transport path to the other in at least one module by a relatively moveably substrate transfer device, e.g., in the front end module 1100 and process module 1400. This allows for a fast transversal movement, possibly leading to reduced tact times. Further, compared to handling a substrate or substrate carrier with a handling device for moving it from one transport path to the other, no possibly detrimental particles are generated when the substrate or substrate carrier is moved with its track.

FIG. 2 illustrates an embodiment of a substrate processing system including only dual-track modules as indicated by the two parallel lines in each of the front end module 1100, first load module 1200, second load module 1300, and (first) process module 1400, and also in the optional module(s) 1500. A substrate processing system including only dual-track modules will be called a dual-track substrate processing system for short. A dual-track substrate processing system according to embodiments described herein can enable substrate processing, e.g., coating with one or multiple layers, either at higher output capacity when using the same amount of process chambers as in current cluster design substrate processing systems or with the same output capacity, but using a reduced number of process chambers as compared to the current cluster design substrate processing systems. Further, fast tact times may be realized, e.g., with process conducts that will be described in more detail herein.

The front end module 1100, the first load module 1200, the second load module 1300 and the process module 1400 are arranged for substrate transfer between every pair of neighboring modules along the transport direction T. The dual-track transfer devices of the modules provide exactly two individual tracks for supporting a substrate or substrate carrier and for moving the substrate or substrate carrier at least in the transport direction. Substrates or substrate carriers may be moved from one transport path T1 to another transport path T2 in at least one of the modules, e.g., in the first and last module of an inline substrate processing system.

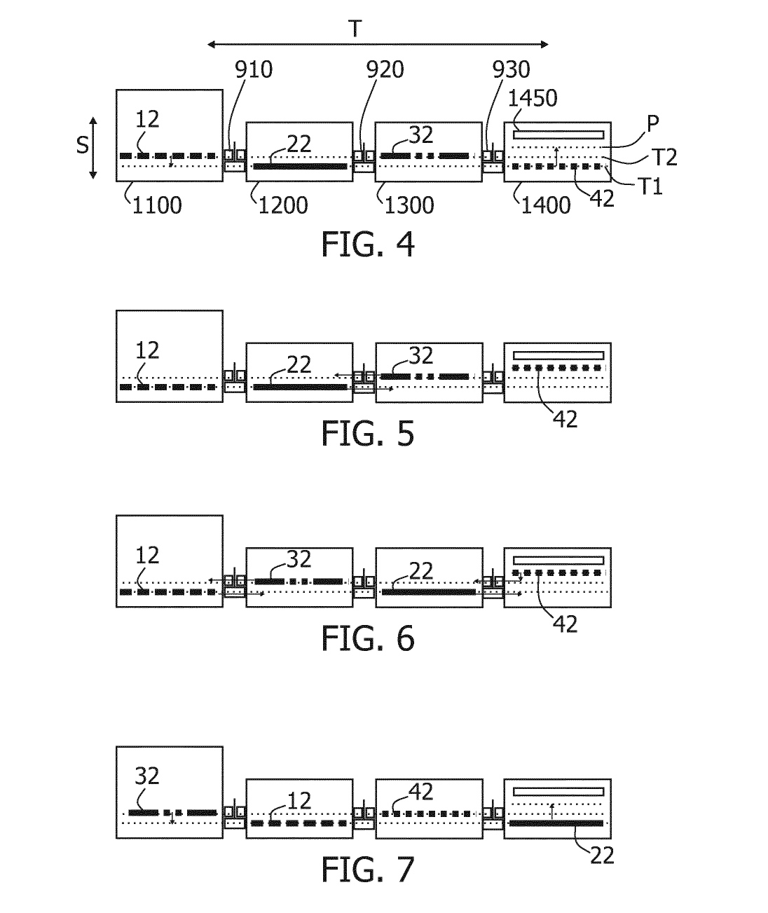

FIG. 3 shows further embodiments of substrate processing systems. According to one embodiment a substrate processing system adapted for depositing one layer on a substrate, e.g., an ITO or IGZO layer, is provided. This substrate processing system is a dual-track substrate processing system. It consists of a relatively moveable dual-track front end module 1100 with two tracks 1112 and 1122 that are moveable relative to each other at least in the switch direction S, a first fixed dual-track load module 1200 with fixed tracks 1215 and 1225, a second fixed dual-track load module 1300 with fixed tracks 1315 and 1325, and a relatively moveable dual-track process module 1400 with two tracks 1412 and 1422 that are moveable relative to each other at least in the switch direction S. A deposition source in the process module 1400 may, e.g., contain a rotary ITO or IGZO sputter target. A possible process conduct for coating substrates with one layer in this substrate processing system will be described with respect to FIGS. 4-7.

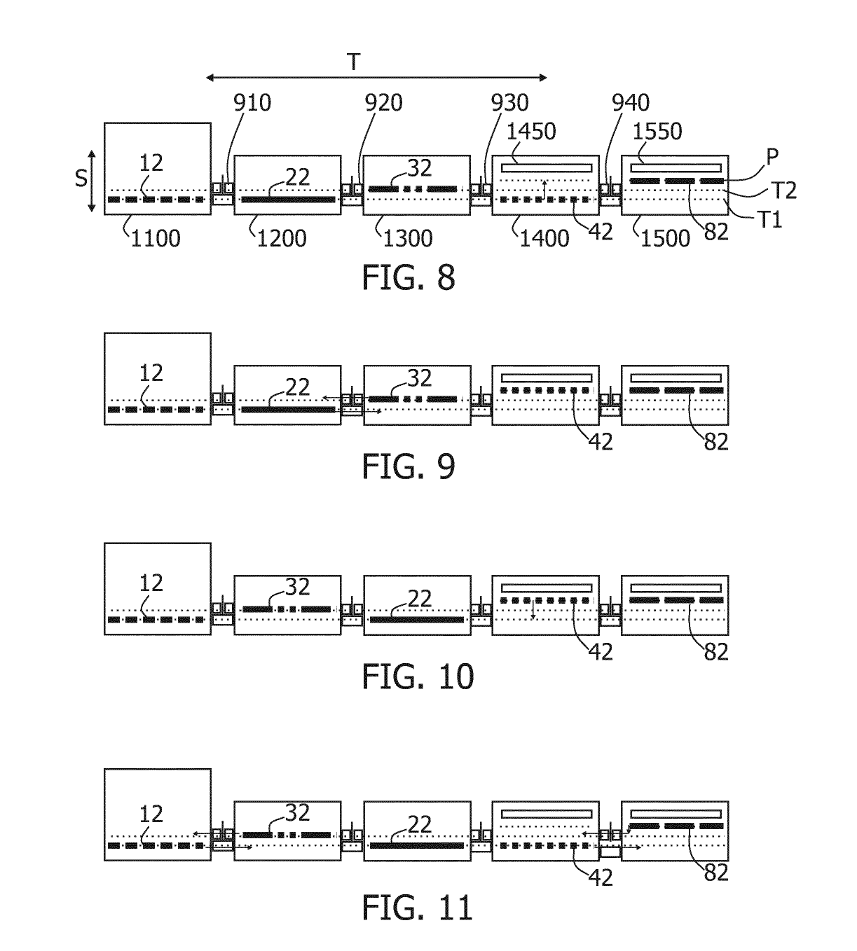

According to a further embodiment shown in FIG. 3, a substrate processing system adapted for depositing three layers on a substrate, e.g., a Mo—Al—Mo layer structure, is provided. This substrate processing system is a dual-track substrate processing system. It consists of a relatively moveable dual-track front end module 1100 with two tracks 1112 and 1122 that are moveable relative to each other at least in the switch direction S, a first fixed dual-track load module 1200 with fixed tracks 1215 and 1225, a second fixed dual-track load module 1300 with fixed tracks 1315 and 1325, a first relatively moveable dual-track process module 1400 with two tracks 1412 and 1422 that are moveable relative to each other at least in the switch direction S, and a second relatively moveable dual-track process module 1500 with two tracks 1512 and 1522 that are moveable relative to each other at least in the switch direction S. A deposition source in the process module 1400 may, e.g., contain a rotary Mo sputter target. A deposition source in the process module 1500 may, e.g., contain a rotary Al sputter target. A possible process conduct for coating substrates with three layer in this substrate processing system will be described with respect to FIGS. 8-14.

A similar substrate processing system may be adapted for depositing two layers on a substrate, e.g., a Mo—Cu layer structure. The process chamber 1400 may then contain a rotary Cu sputter target, and the process chamber 1500 may then contain a rotary Mo sputter target. The transfer device in chamber 1400 need not be a relatively moveable dual-track substrate transfer device in this case. At least, it need not allow track switching or track exchange of the first and second tracks or individual movement of both tracks. The substrate transfer device in chamber 1400 may, e.g, be a dual-track transfer device with one moveable track that can be aligned with the process position and the transport path next to the process position, and with one fixed track positioned on the other transport path.

According to further embodiments, a substrate processing system adapted for depositing three layers on a substrate, e.g., a Mo—Al—Mo layer structure, may include a third process module. A deposition source in the third process module may, e.g., contain a rotary Mo sputter target, while the first and second deposition sources of the first and second substrate process modules contain a Mo and an Al sputter target, respectively. In this embodiment, the first and second process modules can, but need not, include relatively moveable dual-track substrate transfer devices. In some embodiments only the last process module of several process modules provided inline includes a relatively moveable dual-track substrate transfer device with track switching or track exchange capability. The other process modules may include, e.g., a dual-track transfer device with one moveable track that can be aligned with the process position and the transport path next to the process position, and with one fixed track positioned on the other transport path. According to further embodiments, the dual-track front end module may be replaced by a front end module including one or more robots such as a 6-axis robot.

FIGS. 4-7 show a substrate processing system as described with respect to FIG. 3, wherein the front end module 1100 is connected to the first load module 1200 by a lock 910, the first load module 1200 is connected to the second load module 1300 by a lock 920, and the second load module is connected to the process module 1400 by a lock 930. Locks between chambers, including locks 940 and 950 connecting process modules 1400, 1500 and 1600 shown in FIGS. 8-19, allow substrate transfer therethrough between the chambers. At least the locks in a vacuum portion and the locks between load modules may be vacuum-tight, e.g., the locks 920, 930, 940 and 950.

In FIGS. 4-7, and also in FIGS. 8-14 and 15-19, the tracks which are configured for supporting substrates or substrate carriers are not shown. To illustrate substrate or carrier routing, only the substrates or carriers are shown, where arrows indicate the movements subsequent to the state currently shown. In the following, for shortness and without implying any limitation, reference will be made to ‘carriers’. Moreover, it shall be understood that carrier routing typically is a cycle process of which only those parts are shown that are necessary for understanding the complete cycle and any further cycles typically performed thereafter. The states for beginning the discussion are chosen arbitrarily. FIGS. 4-19 describe embodiments of methods of processing substrates as well as embodiments of substrate processing systems adapted to perform every function of the methods, including the carrier routing schemes illustrated in these figures.

FIGS. 4-7 illustrate embodiments using a particular routing scheme wherein one layer is coated on every substrate. In FIG. 4, carrier 12 is located in the front end module 1100 on the second transport path T2, carrier 22 is located in the first load module 1200 on the first transport path T1, carrier 32 is located in the second load module 1300 on the second transport path, and carrier 42 is located in the process module 1400 on the first transport path T1. A processed substrate is unloaded from carrier 12 and a fresh substrate is loaded into carrier 12. Carrier 12 is moved in the switch direction S with the track supporting it to the first transport path T1, the other track performing track switching, and carrier 42 is moved in the switch direction S with the track supporting it to the process position P, the other track performing track switching, leading to the state shown in FIG. 5.

The substrate of carrier 42 receives a coating from deposition source 1450, e.g., an ITO or IGZO coating from rotary sputter targets. Carriers 22 and 32 are simultaneously exchanged between load modules 1200 and 1300, leading to the situation shown in FIG. 6. When coating is complete, carrier 42 is moved to the second transport path T2 in the switch direction. Carriers 22 and 42 are simultaneously exchanged between modules 1300 and 1400, and carriers 12 and 32 are exchanged between modules 1100 and 1200, leading to the situation shown in FIG. 7.

The situation in FIG. 7 is comparable to the situation shown in FIG. 4, only that carrier 32 now holds the position formerly held by carrier 12, carrier 12 holds the position formerly held by carrier 22, carrier 22 holds the position formerly held by carrier 42, and carrier 42 holds the position formerly held by carrier 32. A processed substrate is unloaded from carrier 32 and a fresh substrate is loaded into carrier 32, and the process carries on as described before with the carriers permuted as explained.

In this way, e.g., an ITO layer with a thickness of about 500 A may be deposited on every substrate with a tact time of less than 50 s, such as about 45 s or less, or even about 38 s or less. According to an alternative example, an IGZO layer with a thickness of 500 A may be deposited on every substrate with a tact time of less than 55 s, such as about 51 s or less, or even about 38 s or less.

FIGS. 8-14 illustrate embodiments using a particular routing scheme wherein three layers are coated on every substrate. In FIG. 8, carrier 12 is located in the front end module 1100 on the first transport path T2, carrier 22 is located in the first load module 1200 on the first transport path T1, carrier 32 is located in the second load module 1300 on the second transport path, carrier 42 is located in the first process module 1400 on the first transport path T1, and carrier 82 is located in the second process module 1500 in a process position P, receiving a coating from deposition source 1550. Carrier 42 is moved in the switch direction S with the track supporting it to the process position in module 1400, passing the other track that may remain stationary on the second transport path T2. This leads to the state shown in FIG. 9.

The substrate of carrier 82 still receives a coating from deposition source 1550, e.g., an Al coating from a rotary sputter target, and the substrate of carrier 42 receives a first coating from deposition source 1450, e.g., a first Mo coating from a rotary sputter target. Carriers 22 and 32 are simultaneously exchanged between load modules 1200 and 1300, leading to the situation shown in FIG. 10. When the first coating is complete, carrier 42 is moved to the first transport path T1 in the switch direction. Carrier 82 may still receive the coating from deposition source 1550, e.g., because a thicker coating is needed such as a tick Al coating. This leads to the situation shown in FIG. 11.

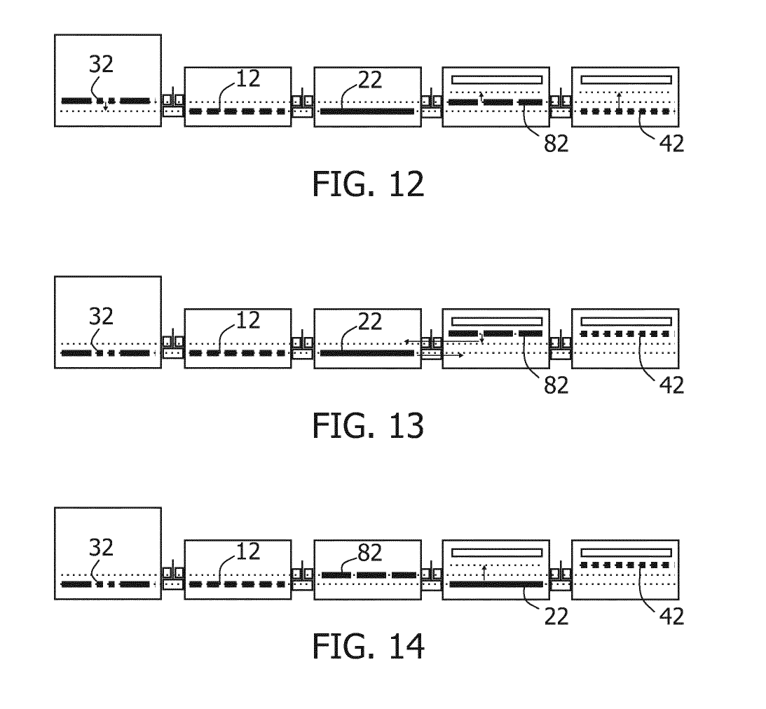

When its coating from deposition source 1550 is complete, carrier 82 is moved to the second transport path T2 in the switch direction. Carriers 42 and 82 are simultaneously exchanged between process modules 1400 and 1500, and carriers 12 and 32 are exchanged between modules 1100 and 1200, leading to the situation shown in FIG. 12. Carrier 82 is moved from the second path T2 to the process position in module 1400 to receive a second coating from deposition source 1450, e.g., a second Mo coating, assuming it already received a first coating in a state prior to that shown in FIG. 8. Carrier 42 is moved from the first transport path to the process position in module 1500 to receive a coating from deposition source 1550. A processed substrate is unloaded from carrier 32 and a fresh substrate is loaded into carrier 32. Carrier 32 is moved from the second transport path T2 to the first transport path T1 in module 1100, leading to the situation shown in FIG. 13.

When the second coating of the substrate of carrier 82 is complete, the substrate of carrier 82 has been coated by three layers, e.g., by a Mo—Al—Mo layer structure. The carrier 82 is moved to the second transport path T2. The substrate of carrier 42 may still receive a coating in module 1500. The carriers 82 and 22 are simultaneously exchanged between modules 1300 and 1400, leading to the situation shown in FIG. 14.

The situation in FIG. 14 is comparable to the situation shown in FIG. 8, only that carrier 32 now holds the position formerly held by carrier 12, carrier 12 holds the position formerly held by carrier 22, carrier 22 holds the position formerly held by carrier 42, carrier 42 holds the position formerly held by carrier 82, and carrier 82 holds the position formerly held by carrier 32. The process carries on as described before with respect to FIGS. 8-13 with the carriers permuted as explained.

In this way, e.g., a Mo—Al—Mo layer structure with a thickness of about 500 A of the first Mo layer, a thickness of about 3500 A of the Al layer, and a thickness of about 500 A of the second Mo layer may be deposited on every substrate with a tact time of less than 80 s, e.g. 75 s, or even less than 70 s.

In a variant, three process modules are provided inline in the order Mo—Al—Mo, wherein only the last process module and the front end module perform track switching, such that the process conduct is a roundabout process similar as in FIGS. 4-7, but with three process modules in the line. While the compact design with only two process modules saves the considerable costs of a further process module, the three-process-module variant with roundabout process conduct may decrease tact time. For instance, tact times of less than 70 s, e.g., 68 s, or even less than 60 s may be achieved. Layer split techniques may be used, e.g., a relatively thick Al layer may be deposited in two consecutive process modules, leading to variants with three and four process modules. This may further reduce tact times, e.g., to 55 s or less such as about 51 s, however at the expense of the additional costs of further process modules.

In a further variant, the substrate processing system shown in FIGS. 8-14 may be used to deposit a two-layer structure such as a Mo—Cu structure. Only the last process module, e.g. the Mo process module, and the front end module perform track switching, such that the process conduct is a roundabout process similar as in FIGS. 4-7, but with two process modules in the line. Deposition of a Mo—Cu layer structure with a Mo layer of about 500 A and a Cu layer of about 6000 A may be performed with a tact time of less than 75 s, e.g. 70 s or less, or even less than 50 s, e.g., about 48 s.

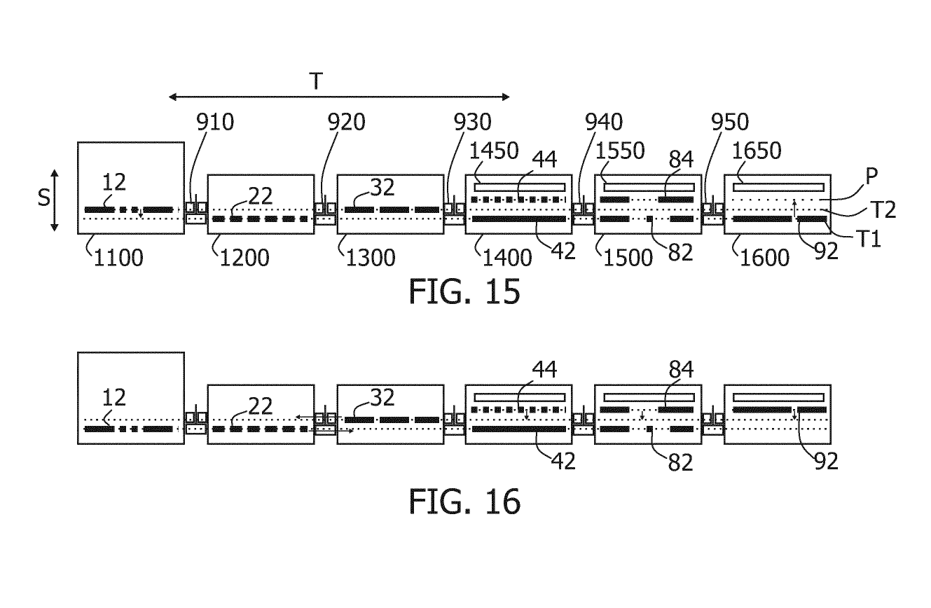

Again, layer split techniques may be used. For instance, if two consecutive Cu process modules are used, so three process modules in total, tact times of less than 50 s, e.g., 45 s or less, such as 38 s may be achieved for the same layer structure, but again at the expense of additional costs for the further process module. FIGS. 15-19 illustrate the deposition of two different layers with layer split technique, e.g., deposition of a Mo—Cu layer structure, which can achieve such tact times.

FIGS. 15-19 illustrate embodiments using a particular routing scheme wherein two different layers are coated on every substrate. In FIG. 15, carrier 12 is located in the front end module 1100 on the second transport path T2, carrier 22 is located in the first load module 1200 on the first transport path T1, carrier 32 is located in the second load module 1300 on the second transport path, carrier 42 is located in the first process module 1400 in a process position, carrier 44 is located in the first process module 1400 on the first transport path T1, carrier 82 is located in the second process module 1500 in a process position P, carrier 84 is located in the second process module 1500 on the first transport path T1, and carrier 92 is located in the third process module 1600 on the first transport path T1. Deposition source 1450 in process module 1400 and deposition source 1550 in process module contain the same target material, e.g., Cu. Carrier 84 receives a first part of a second layer, assuming it has been coated with a first layer in the third process chamber 1600 before, and carrier 44 receives a second part of a second layer, assuming it has been coated with a first part of the second layer in the second process chamber 1500 and with a first layer in the third process chamber 1600 before. Carrier 92 is moved in the switch direction S with the track supporting it to the process position in the third process module 1600. A processed substrate may be unloaded from carrier 12 and a fresh substrate be loaded into the carrier 12. Carrier 12 is moved to the first transport path. This leads to the state shown in FIG. 16.

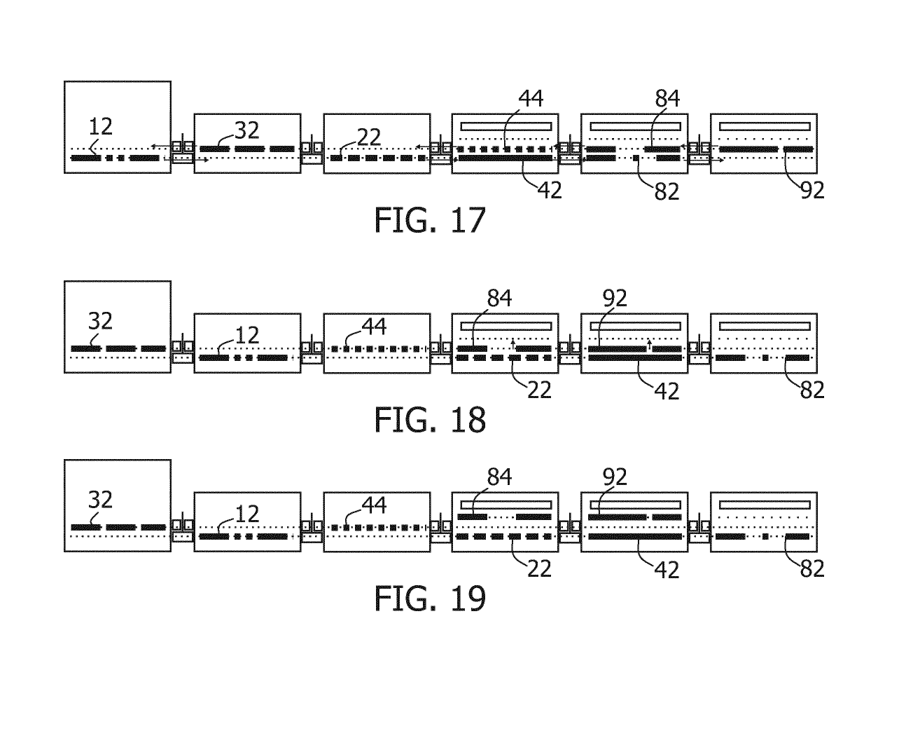

Carriers 22 and 32 are simultaneously exchanged between load modules 1200 and 1300. Once the carriers 44, 84 and 92 have finished their coating step they are each moved to the second transport path, leading to the situation shown in FIG. 17. Carriers 12 and 32 are simultaneously exchanged between modules 1100 and 1200. Carriers 22 and 44 are simultaneously exchanged between modules 1300 and 1400. Carriers 92 and 82 are simultaneously exchanged between modules 1500 and 1600. This leads to the situation shown in FIG. 18.

A processed substrate is unloaded from carrier 32 and a fresh substrate is loaded into carrier 32. Carrier 84 is moved from the second transport path T2 in process module 1400 to the processing position to receive a second part of a second coating from deposition source 1450. Carrier 92 is moved from the second transport path T2 in process module 1400 to the processing position to receive a first part of a second coating from deposition source 1550. This leads to the state shown in FIG. 19.

The situation in FIG. 19 is comparable to the situation shown in FIG. 15, only that carrier 32 now holds the position formerly held by carrier 12, carrier 12 holds the position formerly held by carrier 22, carrier 22 holds the position formerly held by carrier 42, carrier 42 holds the position formerly held by carrier 82, carrier 82 holds the position formerly held by carrier 92, carrier 92 holds the position formerly held by carrier 84, carrier 84 holds the position formerly held by carrier 44, and carrier 44 holds the position previously held by carrier 32. The process carries on as described before with respect to FIGS. 8-13 with the carriers permuted as explained. The process conduct is a roundabout process, where track switching occurs only in the front end module 1100 and the third process module 1600.

In the following, embodiments of transfer devices are described. Further embodiments of transfer devices are also described, in even greater detail, in the PCT application entitled “Substrate transfer device and method of moving substrates” filed on the same day and assigned to the same assignee, attorney docket number 17594P-WO, the content of which is incorporated by reference in its entirety. All these transfer devices may be used in combination with the embodiments of a substrate processing system described herein, yielding yet further embodiments thereof.

A transfer device for substrate transfer along a transport direction and for change between a first transport path and a second transport path extending along the transport direction may be provided in modules of the substrate processing system according to embodiments described herein, e.g., in a relatively-moveable dual-track front end module or in a relatively-moveable dual-track process module. The transfer device may include a first substrate support assembly defining the first track. The transfer device may further include a second substrate support assembly defining the second track. The first substrate support assembly and the second substrate support assembly may be moveable relative to each other at least in the switch direction. The transfer device may include a further substrate support assembly or further substrate support assemblies, defining a further track or further tracks. Any of the further substrate support assemblies may be moveable relative to the first, second and/or other further substrate support assemblies at least in the switch direction. For simplicity, only dual-track substrate transfer devices will be described in the following. It should be understood that any of the features described can also apply to some or all of the substrate support assemblies of triple, quadruple and n-tuple substrate transfer devices without further recitation.

Further, any feature of a transfer device described in paragraphs [0016]-[0029] of said co-pending application may be used in conjunction with transfer devices described herein. These paragraphs and corresponding figure(s) are incorporated herein by reference.

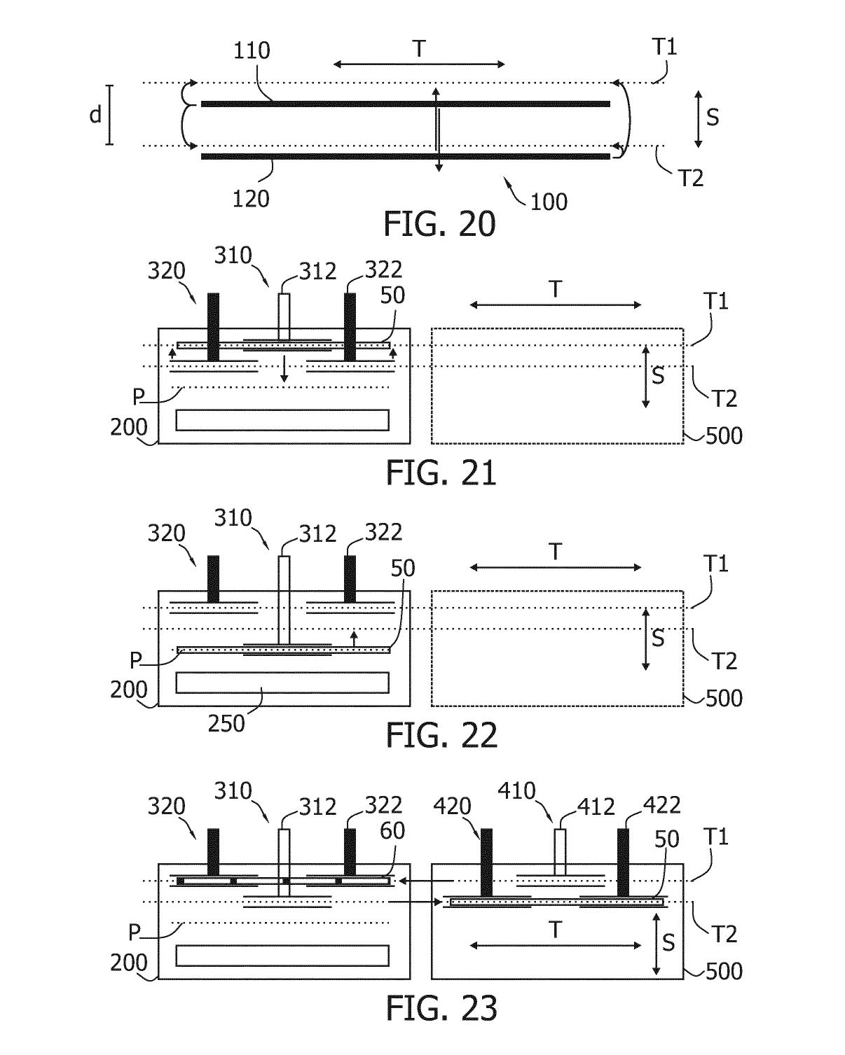

FIG. 20 shows a transfer device 100. Alignment of tracks with transport paths, relative movement of tracks and the situation of tracks passing each other are illustrated. The first transport path T1 and second transport path T2 are separated by a distance d as measured in the switch direction S. The first track is defined by a first substrate support assembly 110, and the second track is defined by a substrate support assembly 120. Substrate support assembly 110 has the option to be aligned with the first transport path T1, and has the option to be aligned with the second transport path T2 as indicated by the curved arrows to the left of substrate support assembly 110. The second substrate support assembly 120 also has the option to be aligned with the first transport path T1, and has the option to be aligned with the second transport path T2 as indicated by the curved arrows to the right of the second substrate support assembly 120. The first substrate support assembly 110 may pass the second substrate support assembly 120, and vice versa, as indicated by the two opposing arrows in the middle of the figure. If the transfer device is used in a process module, the first and second substrate support assemblies may also have the option to be aligned with a process position of the process module.

The previously mentioned co-pending application also discloses further details of modules and the way they are connected and allow substrate transfer. In particular, any feature described in paragraphs [0031]-[0034] of said co-pending application may be used in conjunction with modules described herein. These paragraphs and corresponding figure(s) are incorporated herein by reference.

FIGS. 21-23 illustrate a transfer device and transfer system, and a method how substrates may be moved by the transfer device or transfer system. FIG. 21 shows a first substrate support assembly 310 which includes first support elements 312, and a second substrate support assembly 320 which includes second support elements 322. The schematically illustrated support elements may, e.g., represent magnetic guiding elements or mechanical support elements such as rollers or belts.

As shown in FIG. 21, the first substrate support assembly 310 supports a substrate 50. Support is provided at least partly through the first support elements 312. The support elements 312 are moved to the process position P while supporting the substrate 50 or its carrier. The second support elements 322 of the second substrate support assembly are moved to the first transport path T1. The substrate 50 is moved while it is supported in its track. The substrate 50 and the first support elements 312 pass the second support elements 322 on their way to the processing position P. The first and second support elements 312, 322 may move simultaneously. Alternatively, only one of the sets of support elements moves. For example, the first support elements 312 supporting substrate 50 may move to the process position P first, and then the second substrate support elements 322 move into alignment with the first transport path T1. In any case, there is relative movement between the first and second support elements in the switch direction.

FIG. 22 shows the situation where the substrate 50 is in the processing position P and receives a coating layer from the deposition source 250. After deposition of a layer onto the substrate 50, the first support elements 312 and the substrate 50 move to the second transport path T2 as indicated by the arrow on carrier 50. FIG. 23 shows a further module 500, which might be another process module or load module or front end module. The further module 500 includes a second transfer device.

The second transfer device includes two further substrate support assemblies 410, 420, including substrate support elements 412 and 422, respectively. A second substrate 60 is supported by the substrate support elements 412 in alignment with the first transport path T1. FIG. 23 illustrates a simultaneous transfer of the first substrate 50 from chamber 200 to chamber 500 along the second transport path T2 and of the second substrate 60 from chamber 500 to chamber 200 along the first transport path T1. Support elements 422 of the previously empty support assembly 420 receive the first substrate 50 in chamber 500, and support elements 322 of the previously empty support assembly 320 receive the second substrate 60 in chamber 200. The substrate processing may continue with substrate 60 being moved and coated in a similar way as previously substrate 50.

The previously mentioned co-pending application also discloses further details of support elements, of their type and number. In particular, any feature described in paragraphs [0035]-[0036] and [0043]-[0046] of said co-pending application may be used in conjunction with substrate transfer devices in modules described herein. These paragraphs and corresponding figure(s) are incorporated herein by reference.

The first substrate support assembly may include first support elements, the second substrate support assembly may include second support elements, and at least part of the first support elements and at least part of the second support elements may be moveable relative to each other in an evasion direction. The evasion direction is perpendicular to the transport direction and perpendicular to the switch direction. The first support elements of the first substrate support assembly and the second support elements of the second substrate support assembly may be moveable relatively to each other both in the switch direction and in the evasion direction. The first support elements, or at least parts thereof, may moveable in the evasion direction. Additionally or alternatively, the second support elements, or at least parts thereof, may be moveable in the evasion direction. The first and second support elements, or at least respective parts thereof, may be moveable independently of each other in the evasion direction.

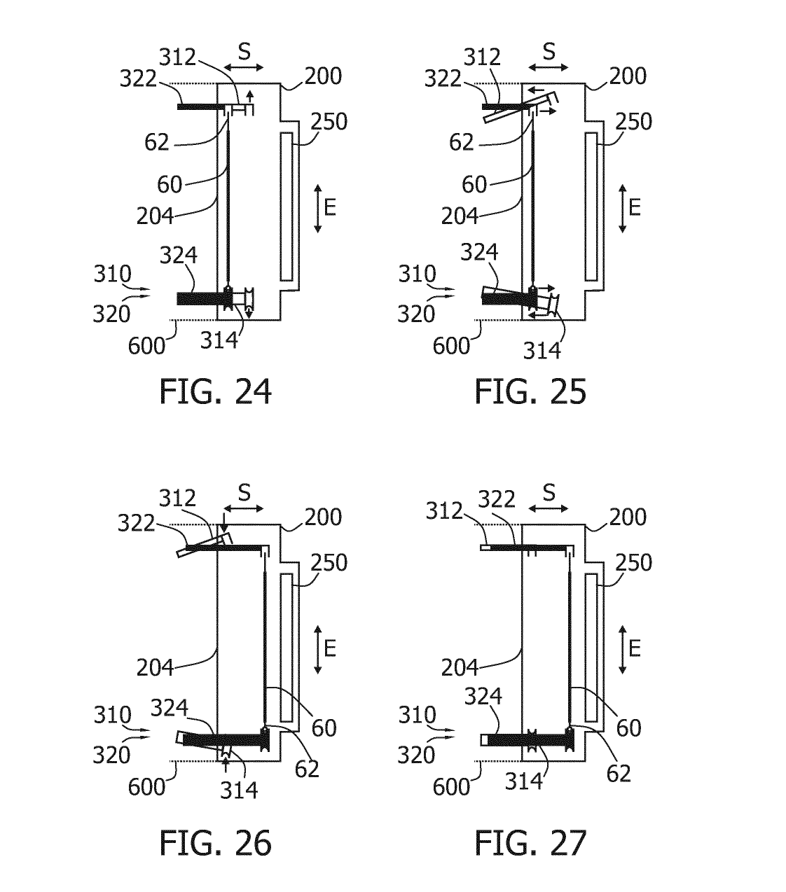

For the evasion movement, support elements may be configured to be tilted. The support elements may take up a displacement in the evasion direction through tiling. FIGS. 24-27 schematically illustrate an evasion movement by tilting. The example shown relates to a vertically aligned substrate 60 and substrate carrier 62. The example can be considered as a specific embodiment realizing a movement of substrate 60 similar to the movement of substrate 50 shown in FIGS. 21 and 22. The tilting angles and other dimensions are exaggerated for illustration.

FIG. 24 shows a vacuum module 200 including a deposition source 250. The vacuum module 200 has a wall 204 opposite the deposition source 250. A transport device includes first and second substrate support assemblies 310, 320. The first substrate support assembly 310 includes a set of rollers 314 and a set of magnetic guiding elements 312. The second substrate support assembly 320 includes a set of rollers 324 and a set of magnetic guiding elements 322, which currently support the substrate carrier 62 that is holding the substrate 60. Axes of the rollers extend through openings in the wall 204 of the vacuum module 200 into a non-vacuum region 600.

Substrate 60 in its carrier 62 is in alignment with the first transport path in FIG. 21. For instance, substrate 60 and substrate carrier 62 may have been transferred into the module along the first transport path, e.g., similarly as shown in FIG. 23. The currently empty support elements 312 and 314 of the first substrate support assembly are moved in the evasion direction E by tilting the axes on which they reside. In the embodiment shown in FIG. 24, the magnetic guiding element(s) 312 are moved upwards, and the roller elements 314 are moved downwards, leading to the situation shown in FIG. 25.

The first substrate support assembly 310 with tilted support elements 312 and 314 is moved in the switch direction S towards the wall 204 as shown in FIG. 25, and the second substrate support assembly 320 with the support elements 322 and 324 supporting substrate carrier 62 is moved in the switch direction S towards the deposition source 250.

In FIG. 26, the substrate carrier 62 and substrate 60 have been moved to the processing position while being supported by the second track. The tilted support elements 312 and 314 can be un-tilted, i.e., their axes can be brought back into a horizontal position once they have passed the substrate 60 and support elements 322, 324 of the second substrate support assembly 320. FIG. 27 shows the situation where the first track is aligned with the first transport path, and the second track with the substrate 60 is aligned with the processing position. The first track defined by the first substrate support assembly 310 and the second track defined by the second substrate support assembly 320 have passed each other. After processing the substrate is complete, the substrate 60 and substrate carrier 62 could be moved to the left into alignment with the second transport path, whereupon an exchange of substrates with a neighboring chamber could take place, similarly as in FIG. 23.

The previously mentioned co-pending application also discloses further details about tilting capabilities of support elements. In particular, any feature described in paragraphs [0048]-[0062] of said co-pending application may be used in conjunction with substrate transfer devices in modules described herein. These paragraphs and corresponding figure(s) are incorporated herein by reference. The co-pending application further discloses an alternative evasion movement in the form of a pivoting movement of substrate support elements. Any feature described in paragraphs [0063]-[0068] may also be used in conjunction with transfer devices in modules described herein. These paragraphs and corresponding figure(s) are incorporated herein by reference.

Transfer devices to be used in conjunction with modules of substrate processing systems of the present disclosures may also include any number of the following features: the first substrate support assembly may be moveable at least in the switch direction such that the first track is alignable with the first transport path and alternatively with the second transport path; the second substrate support assembly may moveable at least in the switch direction such that the second track is alignable with the first transport path and alternatively with the second transport path. The first substrate support assembly and the second substrate support assembly may be moveable relative to each other such that the first track and the second track pass each other in the switch direction. The first substrate support assembly may include first support elements; the second substrate support assembly may include second support elements; at least part of the first support elements and at least part of the second support elements may be moveable relative to each other in an evasion direction perpendicular to both the transport direction and the switch direction. The first support elements may include a first set of magnetic support elements; the second support elements may include a second set of magnetic support elements; at least one of the first and second sets of magnetic support elements may be configured to be pivoted or tilted for taking up a displacement in the evasion direction relative to the respective other set of magnetic support elements. The first support elements may include a first set of roller support elements; the second support elements may include a second set of roller support elements; at least one of the first and second set of roller support elements may be configured to be pivoted or tilted for taking up a displacement in the evasion direction relative to the respective other set of roller support elements. The first and second sets of magnetic support elements may be arranged to support top parts of substantially vertically oriented substrates or substrate carriers; the first and second sets of roller support elements may be arranged to support bottom parts of substantially vertically oriented substrates or substrate carriers; the first and second sets of magnetic support elements may be adapted to be raised and the first and second sets of roller elements are adapted to be lowered. The first sets of magnetic and roller support elements, when holding a substrate or substrate carrier, and the second sets of magnetic and roller support elements can pass each other during relative movement of the first and second substrate support assemblies in the switch direction.

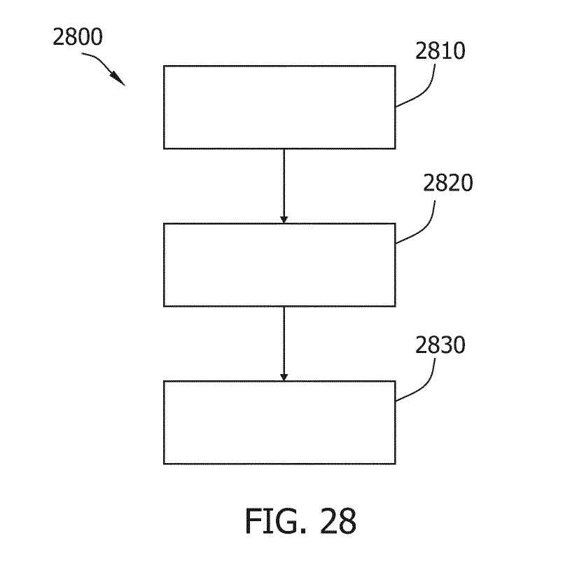

According to further embodiments, methods of processing a substrate in a substrate processing system are provided. According to an embodiment illustrated with a block diagram in FIG. 28, the method 2800 includes, at reference sign 2810, transferring the substrate into a vacuum portion of the substrate processing system along a transport direction. The method further includes, at reference sign 2820, performing relative movement in a switch direction perpendicular to the transport direction in a processing module of the vacuum portion between a first track and a second track, the first track supporting the substrate. The method further includes, at reference sign 2830, depositing a layer onto the substrate in the vacuum processing module.

The method may further include performing relative movement in the switch direction in the processing module between the first track and the second track, the second track supporting the second substrate and the first track being empty, wherein the first track and the second track pass each other during relative movement in the switch direction. The substrate processing system may include a first dual-track load module and a second dual-track load module for transferring substrates into the vacuum portion and for receiving substrates from the vacuum portion. The method may include transferring the substrate from a first stationary track of the first dual-track load module into an empty first stationary track of the second dual-track module and, typically simultaneously, transferring a further substrate from a second stationary track of the second dual-track load module into an empty second stationary track of the first dual-track load module. This action is called (simultaneous) substrate exchange between two modules, in the above example a substrate exchange between two load modules.

The substrate support system may include a dual-track swing module for transferring substrates into the first dual-track load module and for receiving substrates from the first dual-track load module. The method may include performing relative movement in the switch direction in the dual-track swing module between a first track and a second track, wherein the first track supports the substrate. The second track may be empty. The first track and the second track may pass each other during relative movement in the switch direction. The method may further include transferring the substrate from the first track of the dual-track swing module into an empty first stationary track of the first dual-track module and, typically simultaneously, transferring a further substrate from a second stationary track of the first dual-track load module into the second track of the dual-track swing module. In other words, the method may include a (simultaneous) substrate exchange between the swing module and the first load module. The method may further include a substrate exchange or simultaneous substrate exchange between any pair of further modules, e.g., between a load module and a process module, or between a first and second process module.

The method of processing a substrate in a substrate processing system may include a method of moving the substrate in the substrate processing system. The method of moving the substrate may include any of the following: transferring the substrate into a module along a first transport path; moving the substrate in the module at least in a switch direction perpendicular to the first transport path; moving support elements of a, typically empty, substrate support assembly in the module, wherein the substrate and the support elements of the (empty) substrate support assembly are moved relatively to each other in the switch direction and pass each other. Movement of the support elements of the empty substrate support assembly may include at least one of the following: a movement in an evasion direction perpendicular to both the first transport path and the switch direction, and a movement in the switch direction.

The method of moving the substrate may include transferring the substrate so as to be supported by the first track. The first track may be defined by first support elements of a first substrate support assembly. The empty substrate support assembly may be a second substrate support assembly and the support elements of the empty substrate support assembly may be second support elements defining the second track. Moving the substrate may include moving the first track while it is supporting the substrate. The first track supporting the substrate and the second track defined by the second support elements may be moved relatively to each other in the switch direction and may pass each other.

The method may include pivoting or tilting at least part of the second support elements. The module may be a process module having a processing position. Moving the substrate may include moving the substrate to the processing position. The method may include depositing a layer on the substrate in the processing position. The method may include transferring the substrate out of the module along a second transport path, and, typically simultaneously, transferring a second substrate into the module along the first transport path, wherein the second substrate is received by the support elements of the empty substrate support assembly.

The previously mentioned co-pending application discloses further details about methods of moving the substrate, which can be combined with the methods of processing the substrate according to embodiments described herein. In particular, any feature described in paragraphs [0069]-[0077] of said co-pending application may be used in conjunction with methods described herein. These paragraphs and corresponding figure(s) are incorporated herein by reference. Further, any feature of substrate processing systems according to embodiments described herein may be used in methods of processing a substrate, yielding yet further embodiments. Conversely, substrate processing systems and their components may be configured to carry out each of the methods described herein. The use of a substrate processing system according to any of the embodiments described herein to perform any of the methods of processing a substrate described herein is provided according to yet further embodiments.

The terms and expressions which have been employed herein are used as terms of description and not of limitation, and there is no intention, in the use of such terms and expressions, of excluding any equivalents of the features shown and described or portions thereof. While the foregoing is directed to embodiments, other and further embodiments may be devised without departing from the scope, and the scope is determined by the claims that follow.

1. A substrate processing system, comprising:
a front end module;
a load module;
a process module; and
wherein the front end module, load module and process module are arranged for substrate transfer between these modules along a transport direction, and wherein at least one of the front end module, load module and process module comprises a transfer device providing at least two individual tracks for supporting a substrate or substrate carrier, wherein two or more of the at least two tracks are movable relatively to each other in a switch direction perpendicular to the transport direction.

2. The substrate processing system according to claim 1, wherein the front end module is a dual-track swing module comprising a dual-track transfer device providing two tracks for supporting a substrate or substrate carrier, wherein the two tracks are movable relatively to each other in the switch direction.

3. The substrate processing system according to claim 1, wherein the process module is the last module in a row of modules that starts with the front end module, and wherein the process module includes a dual-track transfer device providing two tracks for supporting a substrate or substrate carrier, wherein the two tracks are movable relatively to each other in the switch direction.

4. The substrate processing system according to claim 1, wherein the two tracks of the transfer device of at least one of the front end module and the process module are movable to pass each other in the switch direction.

5. The substrate processing system according to claim 1, comprising at least one of the following:
(a) a second processing module including a dual-track transfer device; and
(b) a third processing module including a dual-track transfer device.

6. The substrate processing system according to claim 1, wherein the load module is a first load module and the substrate processing system comprises a second load module:
wherein the first load module is connected to the front end module and the second load module is connected to the first load module for substrate transfer between these modules;
wherein the first load module is connected to a first pump system adapted to pump down the first load module to an intermediate vacuum, and the second load module is connected to a second pump system adapted to pump down the second load module to a high vacuum; and
wherein the first load module includes a first fixed dual-track transfer device providing two stationary tracks for supporting a substrate or substrate carrier, and the second load module includes a second fixed dual track transfer device providing two stationary tracks for supporting a substrate or substrate carrier.

7. A substrate processing system, comprising:
a front end module;
a first load module;
a second load module; and
a process module;
wherein the front end module, the first load module, the second load module and process module are arranged for substrate transfer between these modules along a transport direction; and
wherein the first load module, the second load module and the process module each comprise a dual-track transfer device which provides exactly two individual tracks for supporting a substrate or substrate carrier and for moving the substrate or substrate carrier at least in the transport direction.

8. The substrate processing system according to claim 7, wherein the substrate processing system is a dual-track substrate processing system, and the front end module is a dual-track swing module providing exactly two individual tracks for supporting a substrate or substrate carrier and for moving the substrate or substrate carrier at least in the transport direction.

9. A method of processing a substrate in a substrate processing system, the method comprising:
transferring the substrate into a vacuum portion of the substrate processing system along a transport direction;
performing relative movement in a switch direction perpendicular to the transport direction in a processing module of the vacuum portion between a first track and a second track, the first track supporting the substrate; and
depositing a layer onto the substrate in the vacuum processing module.

10. The method according to claim 9, wherein the vacuum processing module is dual-track vacuum processing module, wherein the second track is empty, and the first track and the second track pass each other during relative movement in the switch direction.

11. The method according to claim 9, comprising:
transferring the substrate from the first track into a neighboring module; and
simultaneously transferring a second substrate from the neighboring module into the processing module to be supported by the second track, wherein the neighboring module is a second processing module or a load module.

12. The method according to claim 11, comprising:
performing relative movement in the switch direction in the processing module between the first track and the second track, the second track supporting the second substrate and the first track being empty, wherein the first track and the second track pass each other during relative movement in the switch direction.

13. The method according to claim 9, wherein the substrate processing system includes a first dual-track load module and a second dual-track load module for transferring substrates into the vacuum portion and receiving substrates from the vacuum portion, the method comprising:
transferring the substrate from a first stationary track of the first dual-track load module into an empty first stationary track of the second dual-track module and simultaneously transferring a further substrate from a second stationary track of the second dual-track load module into an empty second stationary track of the first dual-track load module.

14. The method according to claim 13, wherein the substrate processing system comprises a dual-track swing module for transferring substrates into the first dual-track load module and for receiving substrates from the first dual-track load module, the method comprising:
performing relative movement in the switch direction in the dual-track swing module between a first track and a second track, the first track supporting the substrate and the second track being empty, wherein the first track and the second track pass each other during relative movement in the switch direction.

15. The method according to claim 14, comprising:
transferring the substrate from the first track of the dual-track swing module into an empty first stationary track of the first dual-track load module and simultaneously transferring a further substrate from a second stationary track of the first dual-track load module into the second track of the dual-track swing module.

16. The substrate processing system according to claim 2, wherein the process module is the last module in a row of modules that starts with the front end module, and wherein the process module includes a dual-track transfer device providing two tracks for supporting a substrate or substrate carrier, wherein the two tracks are movable relatively to each other in the switch direction.

17. The substrate processing system according to claim 2, wherein the two tracks of the transfer device of at least one of the front end module and the process module are movable to pass each other in the switch direction.

18. The substrate processing according to claim 3, wherein the two tracks of the transfer device of at least one of the front end module and the process module are movable to pass each other in the switch direction.

19. The substrate processing system according to claim 1, wherein the two tracks of the transfer device of at least one of the front end module and the process module are movable to pass each other in the switch direction.

20. The substrate processing system according to claim 5, wherein said dual-rack transfer device of the second processing module provides two racks movable relatively to each other in the switch direction.
